(19) United States
(12) Patent Application Publication
(10) Pub. No.: US 2005/0099772 A1
(43) Pub. Date: May 12, 2005

(54) Rear transition module interface enhancement

(76) Inventor: Wen Wei, Beaverton, OR (US)

Correspondence Address: SCHWABE, WILLIAMSON & WYATT, P.C.;PACWEST CENTER, SUITES 1600-1900, 1211 SW FIFTH AVENUE, PORTLAND, OR, 97204, US

(21) Appl. No.: 10/873,580

(22) Filed: Jun. 21, 2004

Related U.S. Application Data
(60) Provisional application No. 60/519,194, filed on Nov. 11, 2003.

(51) Int. Cl. H05K 7/20

(52) U.S. Cl. 361/695

(57) ABSTRACT

A rear transition module interface enhancing apparatus is provided that may allow for creation of a desired standoff distance between a rear transition module and a rear portion a modular platform board, which may enhance modular platform connectivity and/or component accommodation.

### RELATED APPLICATIONS

This application claims the benefit of U.S. Provisional Application No. 60/519,194 filed on Nov. 11, 2003.

### FIELD OF THE INVENTION

Embodiments in accordance with the present invention generally relate to modular computing systems, such as, systems in accordance or in compliance with the specification of the Advanced Telecommunications Computing Architecture (Advanced TCA). More specifically, disclosed embodiments of the invention relate to interface enhancements for Rear Transition Modules in modular platform configurations to enhance modular platform connectivity and performance.

### BRIEF DESCRIPTION OF THE DRAWINGS

Embodiments of the present invention will be readily understood by the following detailed description in conjunction with the accompanying drawings. To facilitate this description, like reference numerals designate like structural elements. Embodiments of the invention are illustrated by way of example and not by way of limitation in the figures of the accompanying drawings:

FIG. 1 illustrates a cross-sectional view of a modular platform in accordance with an embodiment of the present invention; and

FIG. 2 illustrates a cross-sectional view of the modular platform in accordance with an embodiment of the present invention.

### DETAILED DESCRIPTION OF EMBODIMENTS OF THE INVENTION

In the following detailed description, reference is made to the accompanying drawings which form a part hereof wherein like numerals designate like parts throughout, and in which is shown by way of illustration embodiments in which the invention may be practiced. It is to be understood that other embodiments may be utilized and structural or logical changes may be made without departing from the scope of the present invention. Therefore, the following detailed description is not to be taken in a limiting sense, and the scope of embodiments in accordance with the present invention is defined by the appended claims and their equivalents.

Embodiments in accordance with the present invention pertain to enhancing the interfaceability and/or connectivity of modular platforms and modular platform boards. Modular platform boards are used in a variety of modular platform applications, including but not limited to enterprise servers, telecommunications applications, flexi-servers, and the like. Many of these applications have one or more specifications that may govern various parameters of certain particular components of the modular platform and configuration restrictions and/or requirements. One such example of a governing standard is the PCI Industrial Computer Manufacturers Group (PICMG) 3.0 Advanced TCA Specification (Advanced TCA Specification), which is targeted to the next generation of carrier grade communication equipment.

The Advanced TCA Specification may require, for example, that a modular platform include various components, including, but not limited to intake and exhaust plenums, blade racks or modular platform shelves, fan modules for cooling the modular platform boards inserted in the modular platform shelf, power entry modules, a backplane, and the like. Further, certain specifications require a rear interface unit to allow connectivity with the modular platform board.

In Advanced TCA Specification compliant modular platforms, for example, certain modular platform boards may include a connector for a rear transition module (RTM) that may allow for connectivity of the modular platform board with inputs/outputs (I/O) and/or other sources. Further, many specifications require modular platforms to be constrained to certain configurational and dimensional requirements, such as height, width, and length, the amount of room allotted for an RTM may be restricted. Embodiments in accordance with the present invention pertain to enhancing the interfaceability of modular platforms and facilitate higher density stacking of modular platforms within specification dimensional guidelines. Such embodiments may help to increase the density of the modular platforms as well as the microelectronic components that can be supported per modular platform board, per modular platform and per system.

Embodiments in accordance with the present invention may provide an interface enhancing apparatus that can allow for expansion of the number of I/O interface connectors to increase connectivity capability, while observing necessary dimensional restrictions.

Embodiments in accordance with the present invention may also provide an interface enhancing apparatus that can controllably size an RTM standoff distance to allow for placement of components between the RTM and the rear portion of a modular platform board. In one embodiment, the RTM may be configured to allow a power module, such as a power entry module (PEM) in Advanced TCA Specification compliant modular platforms, to be positioned behind the modular platform boards. This in turn may allow for use of dual plenums without the PEM interfering with the exhaust portion of the dual plenum, and thus may allow for higher density modular platform applications.

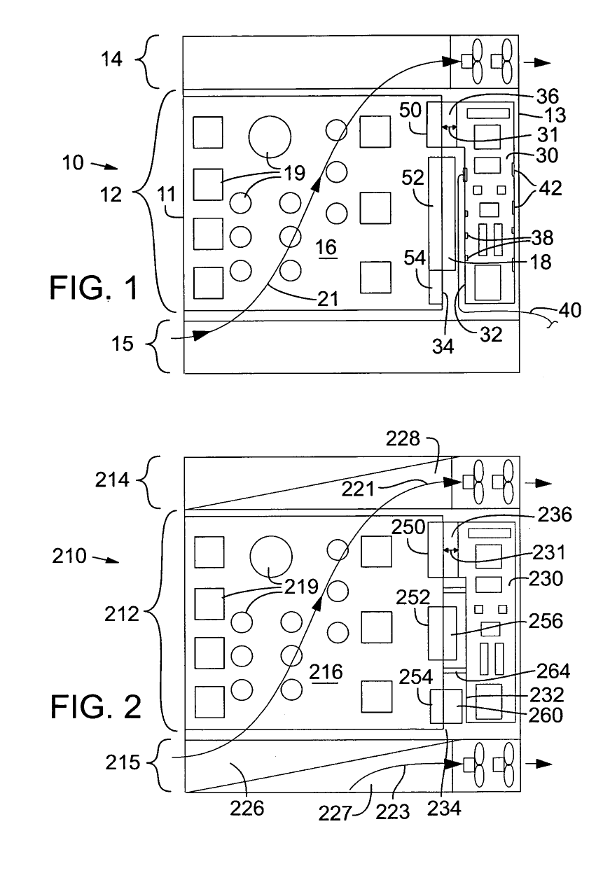

FIG. 1 illustrates a cross-sectional view of a modular platform in accordance with an embodiment of the present invention. Modular platform 10 may include a modular platform shelf 12 having a front side 11 and a rear side 13, an intake plenum 15 and an exhaust plenum 14. Modular platform shelf 12 may include a back plane 18 and be configured to receive modular platform boards 16. Backplane 18 may be configured to interface with the modular platform boards 16, and provide a variety of functions, including, but not limited to power control/distribution to the modular platform boards, management and data transport functions to and between modular platform boards, and act as control and data planes to manage and control data throughput and routing.

Modular platform board 16 may be configured with any number of electronic components 19 to accommodate the necessary functionality required. Such electronic components may include, but are not limited to, microprocessors, chip sets, memory, PCI Express or advance switching compatible components, capacitors, transistors, and the like. The amount and density of electronic components can generate a substantial amount of heat that must be dissipated. Such heat management may include pulling a cooling medium, such as air, through the intake plenum 15, through the modular platform shelf 12, and out exhaust plenum 14, as shown by flow 21.

In addition to multiple electronic components, modular platform board 16 may require a variety of front side and rear side interfaces that may enable connectivity of the modular platform boards with external sources, devices and the like. Such interfaces may include active I/O-type interfaces, such as USB, Institute of Electrical and Electronics Engineers (IEEE) 1394, serial, ethernet, sonnet, and other interface ports, and/or passive interfaces, such as audible and visual indicators.

In one embodiment, modular platform board 16 may include three interfaces 50, 52, and 54. Backplane interface 52 may interface with the modular platform shelf backplane 18. Power entry interface 54 may interface with a power supply module, such as a power entry module (PEM) as set forth, for example, in the Advanced TCA Specification. The PEM may be responsible for supporting the power supply needs to the modular platform. It can be appreciated that the power entry interface 54 may interface with the power supply or PEM through the backplane 18.

RTM Interface 50 may allow each modular platform board 16 to interface with, for example, an RTM. The RTM may be considered an extension of the modular platform board that enhances the modular platform board's connectivity, and may include a variety of outer I/O interface connectors 42 on an outer side of RTM 30. Outer I/O interface connectors 42 may be compatible with a variety of connectors, including but not limited to an Institute of Electrical and Electronics Engineers 1394 connector, an Ethernet connector, a Universal Serial Bus connector, a Serial connector, a co-axial cable connector, a fiberoptic connector, and future types of connectors.

Due in part to the density in which modular platform boards may be positioned (e.g., sixteen modular platform boards required in the Advanced TCA Specification), and the dimensional restrictions of the modular platform shelves, the real estate for outer I/O interface connectors 42 on the RTM 30 may be limited. Such limitations may directly impact and limit the functionality the modular platform boards 16. Additionally, as current Advanced TCA compatible RTMs are typically 70 mm in depth, and couple directly to the RTM interface 50, little room is left between an inner side 32 of the RTM and the rear portion 34 of the modular platform board 16.

An interface enhancement module 36 may be used to mechanically and electrically couple RTM 30 to RTM interface 50. Interface enhancement module 36 may controllably allow for the introduction of an increased standoff distance between the inner side 32 of the RTM 30 and the rear portion 34 of the modular platform board 16 and/or backplane 18. Such an increased standoff distance may allow for an increased level of connectivity for each modular platform board 16, and enhance the functionality of the RTMs and the modular platform boards. The standoff distance may be increased by increasing the length 31 of the interface enhancement module.

In one embodiment in accordance with the present invention, the interface enhancement module 36 may be constructed of a molded plastic material, and configured to interconnect the RTM interface configuration with the interface configuration of the RTM. Interface enhancement module 36 may have a first end with an interface compatible with the RTM interface configuration of the modular platform board, and a second end that is compatible with the interface configuration of the RTM 30. The height and thickness of the interface enhancement module 36 may be selected as necessary to fit within the rear portion of the modular platform. It can be appreciated that the width/thickness may be thin enough to allow another interface enhancement module to interconnect to an adjacent modular platform board. For example, in the case of modular platforms that are governed by the Advanced TCA Specification, the interface enhancement module may have a height of less than or equal to 95.1 mm and a width/thickness of less than or equal to 21.33 mm.

The interface configurations may be the same and compatible with a particular standard, such as the Advanced TCA Specification. It can be appreciated, however, that the first end interface configuration may be different than that of the second end configuration, in which case the Interface enhancement module 36 may be used, for example, to enable electrical communication between modular platform boards of one manufacturer using a certain interface configuration with RTMs manufactured by a different manufacturer using a different interface configuration.

Increasing the standoff distance using an RTM interface enhancement module of a desired length 31 may allow for inner I/O interface connectors 38 to be included on the RTM 30. As much connectivity must be hardwired, the increased standoff distance allows, for example, cabling 40 to be routed within the standoff space created by the RTM interface enhancement module 36, around the RTM 30 and out the rear side 13 of the modular platform shelf 12.

As the distance between the rear portion 34 of the modular platform board 16 and the rear side 13 of the modular platform shelf 12 may be limited, for example by a Specification or by physical constraints, the amount of standoff may be varied by selectively controlling the length 31 of the RTM interface enhancement module 36. The length of the RTM interface enhancement module may be a function of the allowable RTM depth, number of inner I/O interface connectors required, and any dimensional limitation on the overall depth of the modular platform shelf.

FIG. 2 Illustrates a cross-sectional view of a modular platform in accordance with an embodiment of the present invention. Modular platform 210 may include a modular platform shelf 212 adapted to receive modular platform board 216. Modular platform 212 may be coupled to an exhaust portion 228 of a dual plenum 214 and the intake portion 226 of a dual plenum 215, to facilitate heat dissipation through airflow 221.

Modular platform boards 216 may include a plurality of electronic components 219, and may have an RTM interface 250, backplane interface 252 to interface with backplane 256, and a power entry interface 254. Current modular platforms typically position the PEM below the modular platform shelf 212, which normally places the PEM in the intake plenum for the modular platform. However, when using dual plenums 215 and 214, so positioning the PEM may obstruct the an exhaust portion 227 of dual plenum 215, and disturb the exhaust flow 223 of an adjacent modular platform (not shown) sharing dual plenum 215. This may cause the operating temperature to rise above acceptable levels and possibly result in modular platform board failure.

RTM interface enhancement module 236 may be used to increase the standoff distance of the inner side 232 of RTM 230 from the rear portion 234 of modular platform board 216 by increasing length 231. With the increased standoff distance, components, such as PEM 260, may be positioned between the RTM 230 and rear portion 234, such that the PEM 260 may be directly interconnected to power entry interface 254. This may enable the use of a shared plenum such that the PEM will not obstruct the exhaust flow 223 of an adjacent modular platform shelf coupled to exhaust plenum 227 of dual plenum 215.

It can be appreciated that RTM interface enhancement module 236 may be used and sized to enable placement of other components between the RTM and the modular platform board. Further, it can also be appreciated that extending the standoff distance may increase the ability of air to pass over the RTM and components positioned near the rear side of the modular platform shelf to allow for better heat dissipation.

In one embodiment in accordance with the present invention, an alignment mechanism may be used to ensure proper positioning of the RTM and RTM interface enhancement module, and help prevent open or misaligned connections, which may hamper system performance. In one embodiment, one or more members 264 may be coupled to the RTM 230 and directed toward the rear portion 234 of modular platform board 216. Members 264 may be sized such that they contact designated locations on the rear portion 234 that may create positive stops for RTM 230 when it is substantially aligned and properly interconnected to RTM interface enhancement module 236 and RTM interface 250.

It can be appreciated that a variety of alignment mechanisms may be used, including but not limited to alignment pins, guided rails, and the like. Further, modular platform board 216 may have designated receiving positions for the members or other alignment mechanism and may ensure a positive engagement thereof. In one embodiment, the alignment mechanism may provide additional support for the RTM 230, such that the RTM does not shift and cause a compromised interface.

Although certain embodiments have been illustrated and described herein for purposes of description of the preferred embodiment, it will be appreciated by those of ordinary skill in the art that a wide variety of alternate and/or equivalent embodiments or implementations calculated to achieve the same purposes may be substituted for the embodiments shown and described without departing from the scope of the present invention. Those with skill in the art will readily appreciate that embodiments in accordance with the present invention may be implemented in a very wide variety of ways. This application is intended to cover any adaptations or variations of the embodiments discussed herein. Therefore, it is manifestly intended that embodiments in accordance with the present invention be limited only by the claims and the equivalents thereof.

1. A rear transition apparatus, comprising:
a rear transition module configured to mechanically and electrically interconnect to a modular platform board, the rear transition module having an inner side and an outer side; and
an interface enhancement module adapted to removably couple the rear transition module to the modular platform board and sized to provide a desired standoff distance between the inner side of the rear transition module and a rear portion of the modular platform board to provide access to at least a selected one of the inner side of the rear transition module and a rear portion of the modular platform board.

2. The rear transition apparatus of claim 1, wherein at least one of the inner and the outer sides includes one or more input/output (I/O) interface connectors.

3. The rear transition apparatus of claim 2, wherein the inner side and the outer side each includes one or more I/O interface connectors.

4. The rear transition apparatus of claim 1, wherein the desired standoff distance is selected to allow a power entry module to be positioned between the inner side of the rear transition module and the rear portion of the modular platform board.

5. The rear transition apparatus of claim 1, wherein the one or more I/O interface connectors are selected from a group of connectors consisting of an Institute of Electrical and Electronics Engineers 1394 connector, an Ethernet connector, a Universal Serial Bus connector, a Serial connector, a co-axial cable connector, and a fiberoptic connector.

6. The rear transition apparatus of claim 1, wherein the rear transition module includes an alignment mechanism for aligning the rear transition module with the rear portion of the modular platform board.

7. The rear transition apparatus of claim 6, wherein the alignment mechanism includes one or more members sized to contact a corresponding desired location to establish a substantially uniform standoff distance for the rear transition module.

8. A modular platform, comprising:
a modular platform shelf configured to removably receive one or more modular platform boards;
at least one modular platform board having a rear transition module interface;
a rear transition module configured to electrically interconnect to the rear transition module interface, the rear transition module having an inner first side and an outer second side; and
an interface enhancement module adapted to removably couple the rear transition module to the modular platform board and sized to provide a desired standoff distance between the inner side of the rear transition module and a rear portion of the modular platform board to provide access to at least a selected one of the inner side of the rear transition module and the rear portion of the modular platform board.

9. The modular platform of claim 8, wherein at least one of the inner side and the outer side includes one or more input/output (I/O) interface connectors.

10. The modular platform of claim 9, wherein the inner side and the outer side each includes one or more I/O interface connectors.

11. The modular platform of claim 8, wherein the one or more I/O interface connectors are selected from a group of connectors consisting of an Institute of Electrical and Electronics Engineers 1394 connector, an Ethernet connector, a Universal Serial Bus connector, a Serial connector, a co-axial cable connector, and a fiberoptic connector.

12. The modular platform of claim 8, wherein the rear transition module includes an alignment mechanism for aligning the rear transition module with the rear portion of the modular platform board.

13. The modular platform of claim 12, wherein the alignment mechanism includes one or more members sized to contact a corresponding desired location to establish a substantially uniform standoff distance for the rear transition module.

14. The modular platform of claim 8, wherein the desired standoff distance is selected to allow a power entry module to be positioned between the inner side of the rear transition module and the rear portion of the modular platform board.

15. The modular platform of claim 14, further comprising:
a first plenum in fluid communication with the first end of the modular platform shelf and configured to act as an intake for a cooling medium into the modular platform shelf; and
a second plenum in fluid communication with the second end of the modular platform shelf and configured to exhaust the cooling medium from the modular platform shelf.

16. The modular platform of claim 15, wherein the first plenum is a dual plenum having a first intake portion and a first exhaust portion, the first intake portion being in fluid communication with the modular platform shelf, and the first exhaust portion being in fluid communication with a first adjacent modular platform shelf, and wherein the second plenum is a dual plenum having a second intake portion and a second exhaust portion, the second exhaust portion being in fluid communication with the modular platform shelf and the second intake portion being in fluid communication with a second adjacent modular platform shelf.

17. The modular platform of claim 8, wherein the modular platform is at least part compliant with a PCI Industrial Computer Manufacturers Group (PICMG) 3.0 Advanced Telecommunications Computing Architecture standard.

18. The modular platform of claim 17, wherein the interface enhancement module has a width of less than or equal to 21.33 mm and a height of less than or equal to 95.1 mm.

19. A method of enhancing connectivity of a modular platform, comprising:
providing a modular platform having one or more modular platform boards positioned therein, each of the one or more modular platform boards including a rear transition module interface;
providing one or more rear transition modules adapted to couple to the rear transition module interfaces;
selecting an interface enhancement module; and
coupling the rear transition module to the rear transition module interface via the interface enhancement module to create a standoff distance between an inner side of the rear transition module and a rear portion of the modular platform boards to provide access to the inner side of the rear transition modules and rear portions of the modular platform boards.

20. The method of claim 19, wherein selecting an interface enhancement module includes selecting an interface enhancement module having a length sized to create the desired standoff distance.

21. The method of claim 19, selecting an interface enhancement module includes performing the selecting to create a standoff distance sufficient to allow for placement of a power entry module between the rear transition module and the modular platform board.

22. The method of claim 19, selecting an interface enhancement module includes performing the selecting to create a standoff distance sufficient to allow for access to input/output (I/O) connectors disposed at the inner side of the rear transition module.

23. A system, comprising:
a modular platform shelf configured to removably receive one or more modular platform boards;
at least one modular platform board having a rear transition module interface;
a rear transition module configured to electrically interconnect to the rear transition module interface, the rear transition module having an inner first side and an outer second side;
an interface enhancement module adapted to removably couple the rear transition module to the modular platform board and sized to provide a desired standoff distance between the inner side of the rear transition module and a rear portion of the modular platform board to provide access to at least a selected one of the inner side of the rear transition module and the rear portion of the modular platform board; and
a power entry module adapted to supply power to the modular platform.

24. The modular platform of claim 23, wherein the modular platform is at least part compliant with a PCI Industrial Computer Manufacturers Group (PICMG) 3.0 Advanced Telecommunications Computing Architecture standard.

25. A modular platform shelf, comprising:
one or more slots configured to removably receive one or more modular platform boards having a rear transition module interface;
an area positioned toward a rear end of the modular platform shelf, the area configured to accommodate a rear transition module and an interface enhancement module adapted to removably couple the rear transition module to the modular platform board, the interference enhancement module sized to provide a desired standoff distance between an inner side of the rear transition module and a rear portion of the modular platform board to provide access to at least a selected one of the inner side of the rear transition module and the rear portion of the modular platform board.

26. The modular platform shelf of claim 25, further comprising:
a first plenum in fluid communication with a first end of the modular platform shelf and configured to act as an intake for a cooling medium into the modular platform shelf; and
a second plenum in fluid communication with a second end of the modular platform shelf and configured to exhaust the cooling medium from the modular platform shelf.

27. The modular platform shelf of claim 25, wherein the first plenum is a dual plenum having a first intake portion and a first exhaust portion, the first intake portion being in fluid communication with the modular platform shelf, and the first exhaust portion adapted for fluid communication with a first adjacent modular platform shelf, and wherein the second plenum is a dual plenum having a second intake portion and a second exhaust portion, the second exhaust portion being in fluid communication with the modular platform shelf and the second intake portion adapted for fluid communication with a second adjacent modular platform shelf.

28. The modular platform shelf of claim 25, wherein the modular platform is at least part compliant with a PCI Industrial Computer Manufacturers Group (PICMG) 3.0 Advanced Telecommunications Computing Architecture standard.
